(19) United States
(12) Patent Application Publication
(10) Pub. No.: US 2018/0026129 A1
(43) Pub. Date: Jan. 25, 2018

(54) Trench Edge Termination Structure for Power Semiconductor Devices

(71) Applicant: University of Electronic Science and Technology of China, Chengdu (CN)

(72) Inventors: Min REN, Chengdu (CN); Chi XIE, Chengdu (CN); Jiaju LI, Chengdu (CN); Ziqi ZHONG, Chengdu (CN); Zehong LI, Chengdu (CN); Jinping ZHANG, Chengdu (CN); Wei GAO, Chengdu (CN); Bo ZHANG, Chengdu (CN)

(73) Assignee: University of Electronic Science and Technology of China, Chengdu (CN)

(21) Appl. No.: 15/602,122

(22) Filed: May 23, 2017

(30) Foreign Application Priority Data
Jul. 25, 2016 (CN) 201610587297.5

(51) Int. Cl. H01L 29/78; H01L 21/306; H01L 29/40; H01L 29/06; H01L 29/10; H01L 29/417

(52) U.S. Cl. CPC H01L 29/7811; H01L 29/1079; H01L 29/1095; H01L 29/41741; H01L 29/405; H01L 29/0649; H01L 29/0611; H01L 29/0684; H01L 29/0661; H01L 21/30604

(57) ABSTRACT

Edge termination structures for power semiconductor devices (or power devices) are disclosed. The purpose of this invention is to reduce the difficulty of deep trench etching and dielectric filling by adopting an inverted trapezoidal trench. In order to save the area of edge termination and get a high blocking voltage on condition that the angle between the sidewall of the trench and horizontal is large, fixed charges are introduced at a particular location in the trench. Due to the Coulomb interaction between the ionized impurity in the drift region and the fixed charges, the depletion region of the terminal PN junction can extend fully, which relieves the concentration of electric field there. Therefore, the edge termination can exhibit a high breakdown voltage near to that of the parallel plane junction with a smaller area and the reduced technical difficulty of deep trench etching and dielectric filling.

### CROSS REFERENCE

The present application is based on, and claims priority from, Chinese application number 201610587297.5, filed on Jul. 25, 2016, the disclosure of which is hereby incorporated by reference herein in its entirety.

### TECHNICAL FIELD OF THE INVENTION

This invention generally, relates to the field of semiconductor technology, and more particularly to trench edge termination structures for power semiconductor devices.

### BACKGROUND OF THE INVENTION

The blocking voltage of a power device depends mainly on the reverse bias breakdown voltage of particular PN junction in the devices. Influenced by the non-ideal factors at the termination of PN junction, the reverse breakdown voltage of an actual PN junction is much lower than the parallel plane junction. Junction termination is a specifically designed structure to reduce the local electric field intensity improve the reliability and enhance the breakdown voltage of an actual PN junction close to the parallel plane junction. The terminal structure around the active region is a subsidiary structure of PN junction, which enables the active region to withstand extra high voltage.

At present, the terminal structures for power semiconductor devices fabricated by the planar process are usually some extended structures arranged at the edge of the main junction. These extended structures play the main role in broadening the junction depletion region outwards, thereby reducing the electric field intensity and increasing the blocking voltage. Typical extended structures include field plate (FP), field limiting ring (FLR), junction termination extension (JTE) and variable lateral doping (VLD). To achieve high blocking voltage, the extended structures must be long enough to extend the depletion region. Therefore, in high voltage devices, the large extended terminal structures result in the rise of the cost.

Another type of terminal technology is the bevel edge termination. Firstly the edge of the silicon wafer is removed with a precise angle by a physical method. Then the damage during the silicon-removing process is eliminated by chemical etching. Finally, the surface is covered by the passivation layer. The surface electric field distribution and the surface breakdown voltage are improved by the truncated morphology and the surface passivation. Bevel edge termination technology is divided into the positive grinding angle technology and the negative grinding angle technology. Neither of them is applicable to the square chip, and their occupied areas are very large, especially the negative grinding angle technology.

Trench type terminal technology takes advantage of planar process and bevel process. Deep trenches around the active region are etched and filled with insulating dielectric. The PN junction is cut off by the trench, and the surface electric field distribution and the breakdown voltage are improved by the truncated morphology. The advantage of this kind of trench termination is that the occupied area is small, while the disadvantages are that the deep trench process is more complex, and the breakdown is affected by the trench wall morphology, trench filling material, and other factors. If the sectional shape of the trench is rectangular, as shown in FIG. 3, the electric field concentrates at the terminal PN junction and trench corners, resulting in lower breakdown voltage. If the profile shape of the deep trench is regular trapezoid, as shown in FIG. 4, which is similar to the positive grinding angle of bevel technology, the depletion region of the terminal PN junction can extend and the peak value of electric field can drop, so that the breakdown voltage of this junction termination will get close to that of the parallel plane junction. However, the process to fabricate such a regular trapezoid trench and fill it well is difficult. If the profile of deep trench is an inverted trapezoid, as shown in FIG. 5, which is similar to the negative grinding angle of bevel technology, a small angle between the sidewall of the trench and the horizontal plane is needed to extend terminal PN junction depletion region and enhance the breakdown voltage. However, this scheme needs a very large area.

### SUMMARY OF THE INVENTION

The present invention provides an edge termination structure with a trench for power semiconductor devices to achieve smaller area and higher blocking voltage and to reduce the technical difficulty of trench etching and dielectric filling at the same time.

According to an aspect of the invention, an edge termination is provided. The edge termination includes: a P-type heavily doped substrate 2 (i.e., a heavily doped substrate of a conductivity type P), a P-type lightly doped drift region 3 (i.e., a lightly doped drift region of the same conductivity type P) located on the top surface of the P-type heavily doped substrate 2, a metal drain electrode 1 located on the lower surface of the P-type heavily doped substrate 2, and a field oxide S on the upper surface of the P-type lightly doped drift region 3. The P-type lightly doped drift region 3 includes a trench 4 and a P-type heavily doped region 9 (i.e., a heavily doped region of a conductivity type P). The P-type heavily doped region 9 is located in the top portion of the P-type lightly doped drift region 3 and on the side away from the device active region, and the upper, surface of the P-type heavily doped region 9 contacts the lower surface of the field oxide 8. The trench 4 is filled with insulating material and its upper surface contacts the lower surface of the field oxide 8. In trench 4, there is a polysilicon floating island 5 that stores positive charge. The sidewall of the trench 4 that is close to the active region contacts the N-type junction 6 in the active region, and the upper surface of the polysilicon floating island 5 should be lower than the lower surface of the N-type junction 6 in the active region. In the cross-sectional view of the device, the trench 4 has an inverted trapezium shape, and the value of the angle between the hypotenuse of the inverted trapezium and the horizontal plane ranges from 60 to 90 degrees.

According to another aspect of the invention, an edge termination is provided. The edge termination includes: an N-type heavily doped substrate 2 (i.e., a heavily doped substrate of a conductivity type N) an N-type lightly doped drift region 3 (i.e., a lightly doped of the same conductivity type N) located on the top surface of the N-type heavily doped substrate 2, a metal drain electrode 1 located on the lower surface of the N-type heavily doped substrate 2, and a field oxide 8 located on the upper surface of N-type lightly doped drift region 3. The N-type lightly doped drift region 3 includes a trench 4 and a N-type heavily doped region 9 (i.e., a heavily doped region of a conductivity type N). The N-type heavily doped region 9 is located in the top portion of the N-type lightly doped drift region 3 and on the side away from the device active region, and the upper surface of the N-type heavily doped region 9 contacts the lower surface of the field oxide 8. The trench 4 is filled with an insulating material whose upper surface contacts the lower surface of the field oxide 8. In the trench 4, there is a polysilicon floating island 5 that stores negative charge. The sidewall of the trench 4 that is close to the active region contacts the P-type junction 6 in the active region, and the upper surface of the polysilicon floating island 5 should be lower than the lower surface of the P-type junction 6 in the active region. In the cross-sectional view of the device, the trench 4 has an inverted trapezium shape, and the value of the angle between the hypotenuse of the inverted trapezium and the horizontal plane ranges from 60 to 90 degrees.

Some beneficial effects of the present invention are as follow. On one hand, compared with fabricating a trapezoidal or rectangle trench, fabricating a trench with a sectional shape of inverted trapezium by deep trench etching and dielectric filling is less difficult. On the other hand, due to the Coulomb interaction between the ionized impurity in the drift region and the fixed charges introduced at a particular location in the trench, the depletion region of the terminal PN junction can be fully extended such that the concentration of electric field, is relieved. Therefore, the edge termination provided in this invention can exhibit a high breakdown voltage which approaches the high breakdown voltage of the parallel plane junction with a smaller area.

### BRIEF DESCRIPTION OF THE DRAWINGS

FIG. 1 shows a cross-section of an edge termination structure of power semiconductor devices in accordance with the present invention.

FIG. 2 shows the depletion lines of the edge termination When a high voltage is applied to the drain electrode of the power semiconductor device.

FIG. 3 shows a cross-section of conventional trench edge termination.

FIG. 4 shows the depletion lines of the edge termination with a regular trapezoidal trench when a high voltage is applied to the drain electrode of the device.

FIG. 5 shows the depletion lines of the edge termination with an inverted trapezoidal trench when a high voltage is applied to the drain electrode of the device.

FIGS. 6-15 show diagrammatic sectional views of steps for fabricating the device in accordance with the present invention.

FIG. 16 shows a further exemplary embodiment of a semiconductor component according o the invention.

### DETAILED DESCRIPTION OF THE INVENTION

In the following detailed description, the features of the various exemplary embodiments may be understood in combination with the drawings.

### Embodiment 1

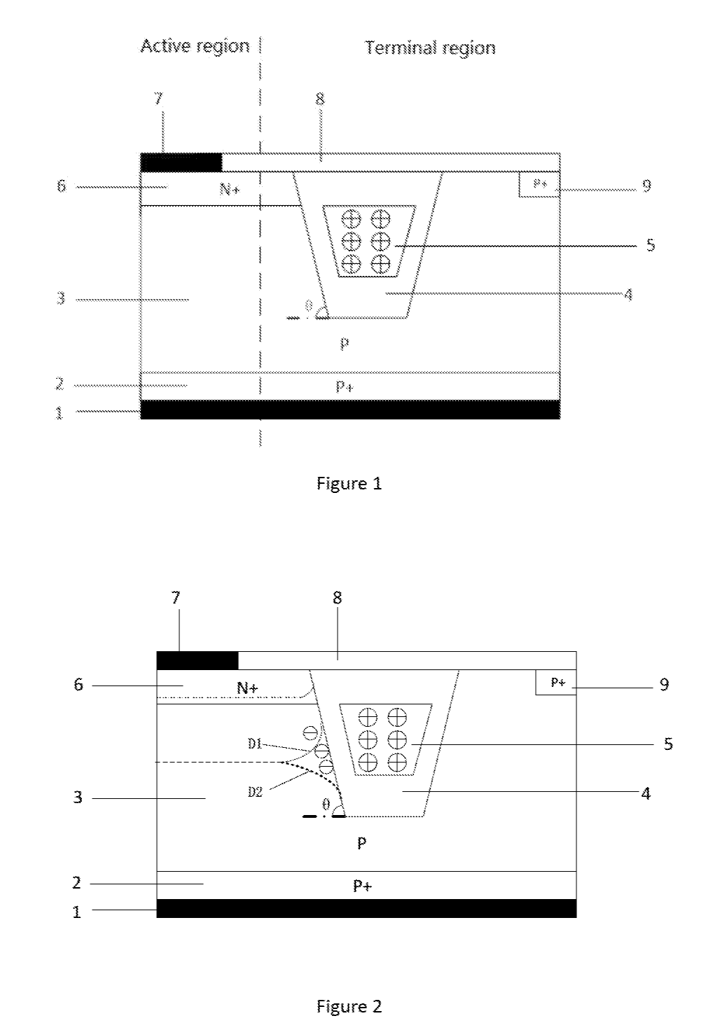

FIG. 1 illustrates a trench edge termination of power semiconductor device in accordance with the present invention. The edge termination structure includes: a P-type heavily doped substrate 2, a P-type lightly doped drift region 3 located on the top surface of the P-type heavily doped substrate 2. a drain electrode 1 located on the lower surface of the P-type heavily doped substrate 2, and a field oxide 8 on the upper surface of the P-type lightly doped drift region 3. The P-type lightly doped drift region 3 includes a trench 4 and a P-type heavily doped region 9. The P-type heavily doped region 9 is located in the top portion of the P-type lightly doped drill region 3 and on the side away from the device active region, and the upper surface of the P-type heavily doped region 9 contacts the lower surface of the field oxide 8. The trench 4 is filled with an insulating material and its upper surface contacts the lower surface of the field oxide 8. In trench 4, there is a polysilicon floating island 5 that stores positive charge. The sidewall of the trench 4 that is close to the active region contacts the N-type junction 6 in the active region, and the upper surface of the polysilicon floating island 5 should be lower than the lower surface of the N-type junction 6 in the active region. In the cross-sectional view of the device, the trench 4 has an inverted trapezium shape, and the value of the angle between the hypotenuse of the inverted trapezium and the horizontal plane ranges from 60 to 90 degrees.

The mechanism of the present edge termination structure provided by embodiment 1 will be explained as follows.

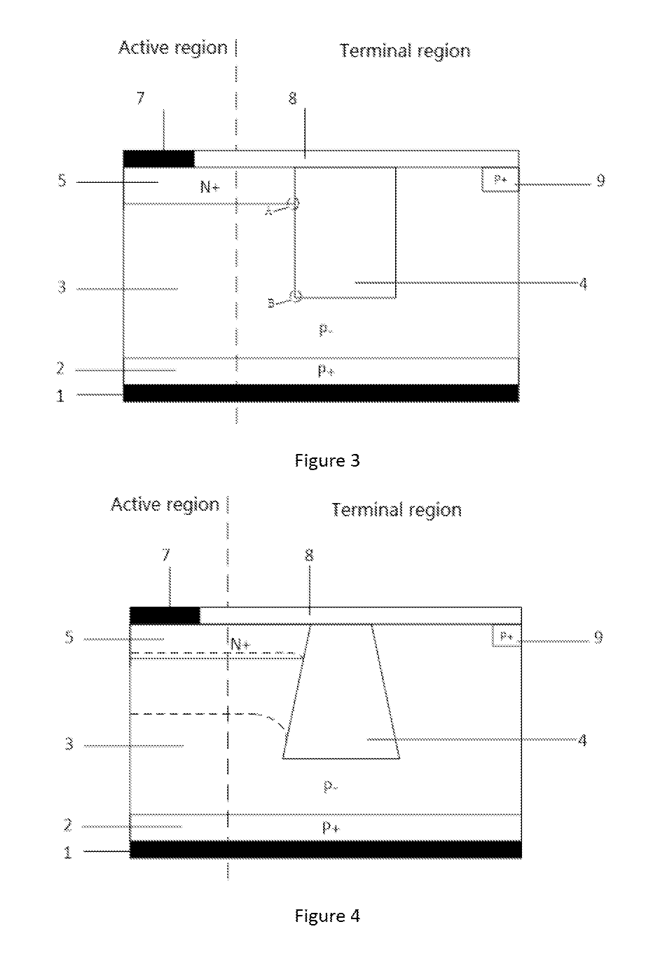

Compared with the planar termination structure, the trench termination structure can greatly reduce the area of the termination while increasing the withstand voltage of the device. However, in an edge structure with a conventional trench, as shown in FIG. 3, influenced by the factors such as the filler, the flatness, and the charge on the surface of the groove wall, the electric field is greatly concentrated at the termination of PN junction (point A in the drawing) and the corners of the trench (point B in the drawing) where the breakdown is easy to take place. Therefore, the traditional trench structure is only applicable to those devices with low withstand voltage.

FIG. 4 shows an edge termination structure with a regular trapezoidal trench. The trench will take away more charges from the lightly doped P-type region than that from the heavily doped P-type region. When a high voltage is applied to the anode, the depletion line will extend a lot to the P-type lightly doped region 3 to maintain charge balance. As the depletion area is widened, the concentration of the electric field at the edge of the main junction 5 can be greatly relieved, so that the breakdown occurs in the body and the breakdown voltage increases. Nevertheless, to fabricate a high-quality deep groove with a positive bevel angle is difficult. Moreover, filling a dielectric material into such a groove without holes is also a challenge. There is likely to be an unfilled condition on both sides of the trench. In addition, deviation may occur in etching a groove with a vertical angle.

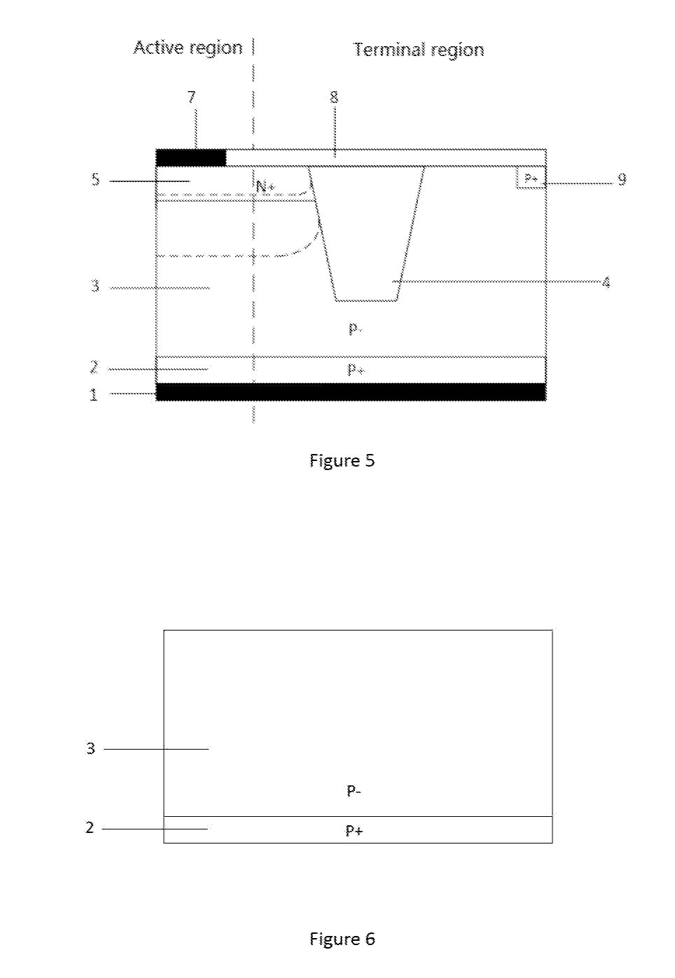

It is much easier to etch a groove with a negative angle, but the trench with a negative angle will take away more charges from the heavily doped N-type region than that from the lightly doped P-type region. As a result, the depletion region will extend in the N-type region while shrinking in the P-type region, as shown in FIG. 5. The depletion region extends less in the N-type region because it is heavily doped. Therefore, the width of depletion region near the sidewall of the trench is smaller than that in the body. This means the electric field intensity in the edge is higher than that in the body, which leads to breakdown on the surface. Thus the breakdown voltage of trench termination with negative angle is lower Though a minimal negative angle (less than 10 degrees) will decrease the electric field intensity on the surface significantly, the angle will increase the area of termination.

FIG. 1 shows the trench edge structure provided by the present embodiment. An inverted trapezoidal trench is etched near the main junction 6 of an N-type semiconductor. A polysilicon floating island of with positive ions (such as cesium ion) is introduced in the trench. The charges are fixed in the floating island as the island is surrounded by a dielectric. As depicted in FIG. 2, the holes in the surface of the P-type region near the trench will be repelled as a result of the Coulomb interaction caused by the positive charge in the floating island, and thus the negative space charge region will be formed. The boundary of depletion region will change from D1 to D2 (D1 and D2 are the boundaries of depletion regions without and with the positive charges in the floating island, respectively). The concentration of electric field will be relieved as the boundary of depletion region extends to the lightly doped P-type drift region. Thus the breakdown voltage of the termination can approach the breakdown voltage of the parallel plane junction.

It should be noted that the upper surface of the floating island 5 should be aligned with or lower than the bottom of the N-type region 6. Otherwise, the charges in the floating island will not be efficient to improve the electric field at the terminal junction.

In this embodiment, the angle θ between the sidewall of the trench and the horizontal plane need not be as small as the angle in a negative bevel junction. The angle θ usually ranges from 60 to 90 degrees. In this way, not only the area of the trench is reduced, but also the difficulties of trench etching and dielectric filling are decreased. Therefore, the trench termination structure provided by the present invention can achieve the breakdown voltage of an ideal parallel plane junction while reducing the termination area and technical difficulty.

In embodiment 1, the structure of the present invention can be produced by the following steps.

As shown in FIG. 6, a P-drift region 3 with relatively low doping concentration is epitaxially grown on the P+ substrate 2. Then a thin pre-oxidized layer is grown on the surface of the silicon wafer.

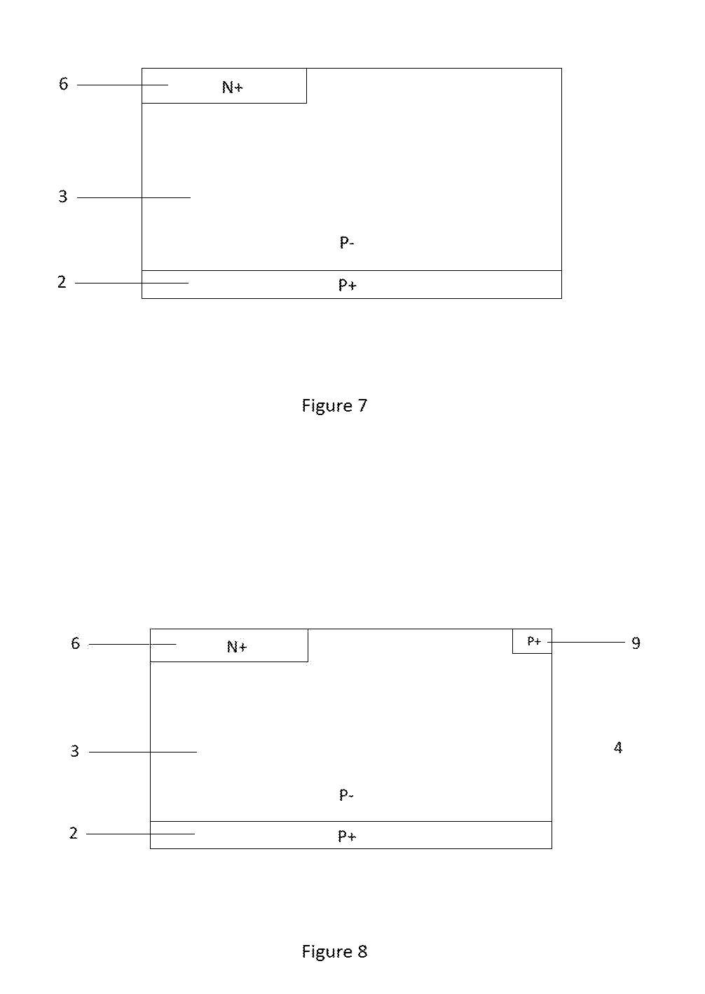

Firstly, an N-type semiconductor material doped region 6 is formed phosphorus ion implantation after lithography of the active region. A thermal propulsion process is used to make the N-type doped region 6 reach a certain junction depth, and the impurities is activated under a high temperature, as shown in FIG. 7.

Then, a P-type heavily doped region 9 is formed by lithography in the terminal region and boron ion implantation, as shown in FIG. 8.

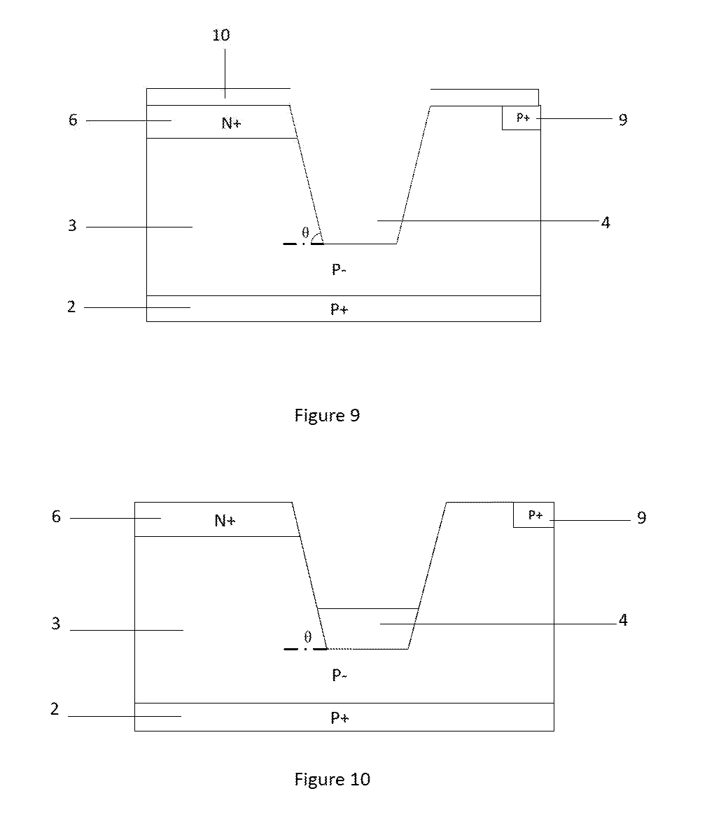

Next, a hard mask layer 10 (such as silicon nitride) is deposited on the surface of the silicon wafer as a barrier layer for subsequent etching. Then the hard mask layer 10 is etched after the lithography and then the deep trench is etched by the shelter of the hard mask layer 10. The etching process may be ion beam etching or plasma etching. After that, an inverted trapezoidal trench 4 is etched in the terminal region, as shown in FIG. 9.

Subsequently, the trench 4 is filled with an insulator (such as silicon dioxide), then the insulator is etched back to an appropriate thickness, as shown in FIG. 10.

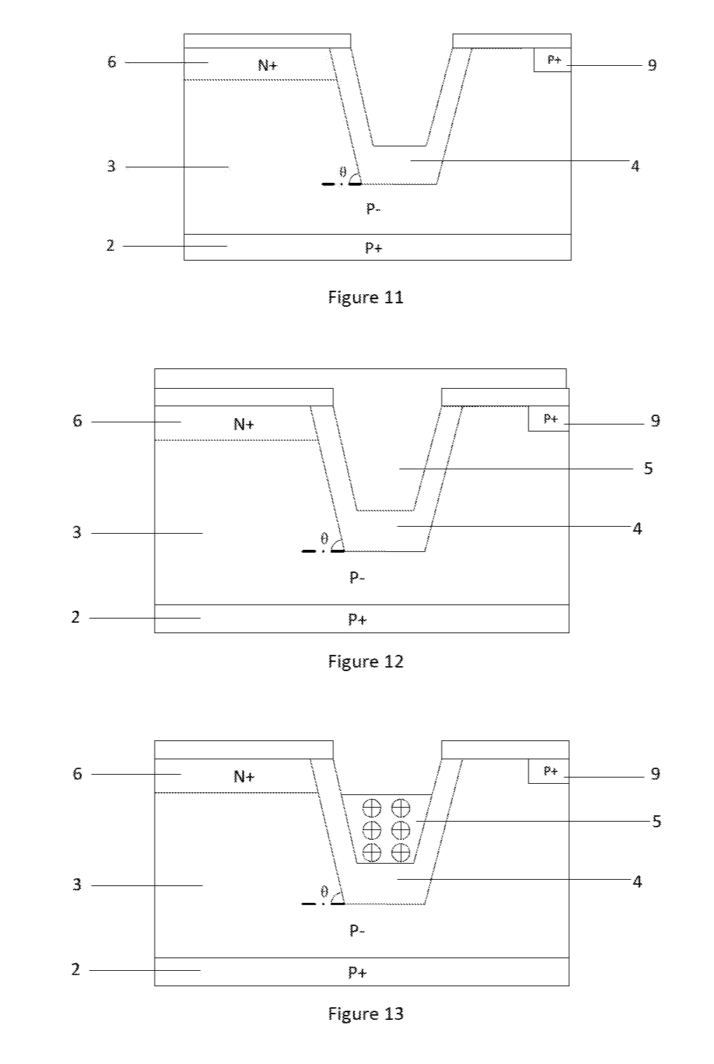

After that, an oxide layer of a certain thickness is grown on the sidewall of the trench 4, as shown in FIG. 11.

After the growth of the oxide layer, the trench 4 is filled with polysilicon 5, as depicted in FIG. 12.

Then the polysilicon 5 is etched back to ensure that the upper surface of the polysilicon 5 is lower than the bottom of the N-type doped region 6. Then cesium ions with a positive charge are implanted into the polysilicon 5 by ion implantation technique, as shown in FIG. 13.

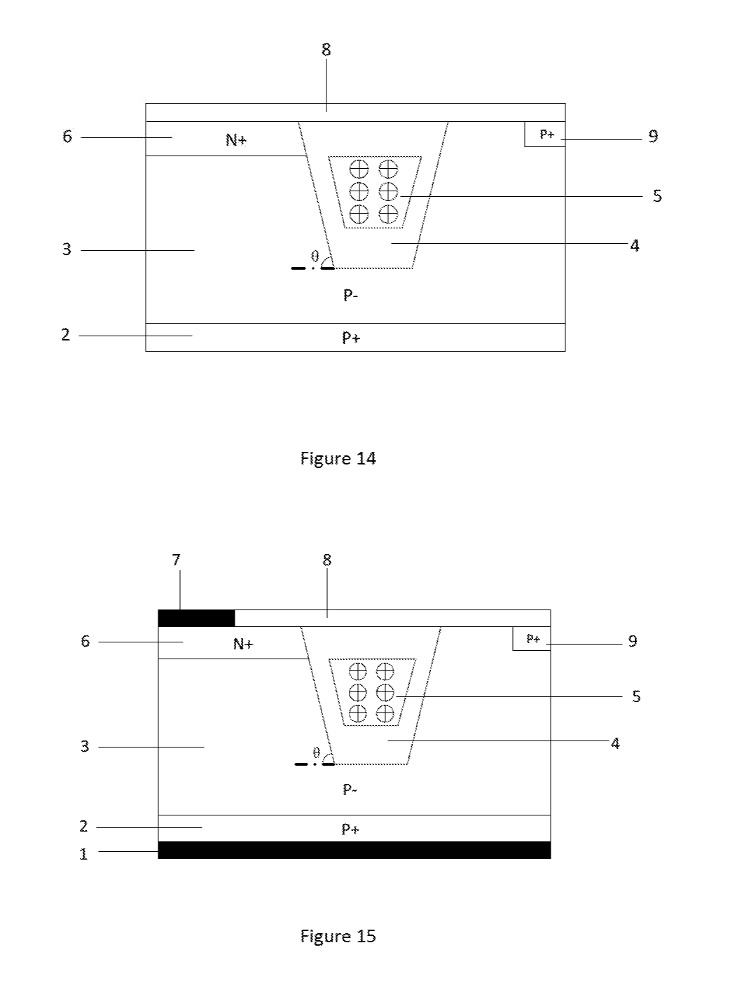

At last, the insulator is deposited on the upper of the polysilicon 5 and the surface of the device, as shown in FIG. 14. A contact hole is etched. Metal is deposited and etched back. Thus the source electrode 7 is formed. Then the back of the wafer is thinned and the drain electrode 1 is formed by metallization, as shown in FIG. 15.

### Embodiment 2

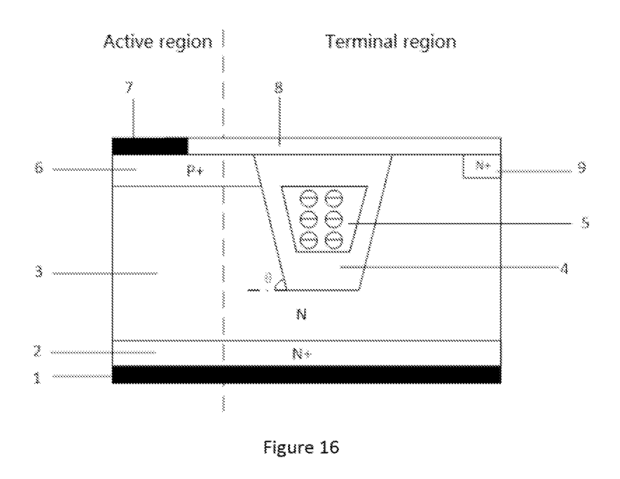

FIG. 16 shows a further embodiment. In this embodiment, on the basis of embodiment 1, all the N-type materials are replaced by P-type materials, and all P-type materials are replaced by N-type materials, and the fixed positive charge in the floating island 5 is replaced by fixed negative charge.

In addition, in both embodiment 1 and embodiment 2. some other semiconductor materials such as silicon, carbide, gallium arsenide, indium phosphide and germanium silicon can be used to replace silicon in manufacturing.

What is claimed is:

1. A trench termination structure of a power semiconductor device, comprising:
a heavily doped P-type substrate;
a lightly doped P-type drift region on an upper surface of the heavily doped P-type substrate;
a metal drain electrode on a lower surface of the heavily doped P-type substrate; and
a field oxide layer on an upper surface of the lightly doped P-type drift region,
wherein the lightly doped P-type drift region includes a trench and a heavily doped P-type region;
the heavily doped P-type region is located in a top portion of the lightly doped P-type drift region and on a side away from an active region of the power semiconductor device;
an upper surface of the heavily doped P-type region contacts a lower surface of the field oxide layer;
the trench is filled with an insulating material whose upper surface contacts a lower surface of the field oxide layer;
a polysilicon floating island that stores positive charges is located in the trench;
a sidewall of the trench on a side near the active region contacts a N-type semiconductor main junction;
an upper surface of the polysilicon floating island is lower than a lower surface of the N-type semiconductor main junction;
a cross-sectional shape of the trench is an inverted trapezium; and
an angle between the sidewall and a horizontal plane is in the range of 60 to 90 degrees.

2. A trench termination structure of a power semiconductor device, comprising:
a heavily doped N-type substrate;
a lightly doped N-type drift region on an upper surface of the heavily doped N-type substrate;
a metal drain electrode on a lower surface of the heavily doped N-type substrate; and
a field oxide layer on an upper surface of the lightly doped N-type drift region,
wherein
the lightly doped N-type drill region includes a trench and a heavily doped N-type region;
the heavily doped N-type region is located in a top portion of the lightly doped N-type drift region and on a side away from an active region of the power semiconductor device;
an upper surface of the heavily doped N-type region contacts a lower surface of the field oxide layer;
the trench is filled with an insulating material whose upper surface contacts a lower surface of the field oxide layer:
a polysilicon floating island that stores negative charges is located in the trench;
a sidewall of the trench on a side near the active region contacts a P-type semiconductor main junction;
an upper surface of the polysilicon floating island is lower than a lower surface of the P-type semiconductor main junction;
a cross-sectional shape of the trench is an inverted trapezium: and
an angle between the sidewall and a horizontal plane is in the range of 60 to 90 degrees.
